(19) United States
(12) Patent Application Publication
(10) Pub. No.: US 2024/0170175 A1
(43) Pub. Date: May 23, 2024

(54) Method for Enhancing/Modifying Fluid Dynamics, Reaction Rates (Including Biological reaction rates), Combustion, Acoustics, Optics and Electronics, with Passive and Real-time modification of these properties.

(71) Applicant: Balam-Quitze Ramos, Watsonville, CA (US)

(72) Inventor: Balam-Quitze Ramos, Watsonville, CA (US)

(21) Appl. No.: 17/991,167

(22) Filed: Nov. 21, 2022

(51) Int. Cl. G21K 1/00

(52) U.S. Cl. CPC G21K 1/006

(57) ABSTRACT

Methods for generating Bose-Einstein condensates (BECs) and excitons at room temperature in certain materials, and enhancing lattice vibration that enhances fluid dynamics, catalyzing reactions, acoustics modification, optics and electronics modification, real-time combustion modification, optics enhancement etc., are disclosed in the present invention.

### CROSS REFERENCE TO RELATED APPLICATIONS

None.

### STATEMENT REGARDING FEDERALLY SPONSORED RESEARCH OR DEVELOPMENT

This invention was not federally sponsored.

### BACKGROUND OF THE INVENTION

### Field of the Invention

The present invention relates to methods for enhancing/modifying material/fluid properties, primarily by stimulating exciton, polariton, and/or Bose-Einstein Condensate (BEC) formation within materials/fluids or molecules, and obtaining the enhanced properties they offer, such as zero resistance electrical conductivity, zero resistance thermal conductivity, etc. This may occur at any temperature at or below the thermal breakdown temperature of the materials. Through the direct or indirect excitement of Bose-Einstein condensates within a material, its various properties can be enhanced or modified. Enhancement of properties in optics and fluid dynamics can be achieved by providing the materials and/or fluids a way to form and sustain excitonic, polaritonic, and BEC phenomenon. These phenomenon can then function to reduce energy of activation, reduce drag and boundary layer effects and conduct energy and/or light and information without resistance. A significant percentage of superconductivity, superfluidity (including superfluid light), and their associated effects can be imparted to materials and fluids at room temperature or at any temperature at or below the thermal breakdown temperature of the materials. More particularly, the invention relates to methods for generating Bose-Einstein condensates, excitons (including exciton condensates), and/or polaritons at room temperature in certain materials, and then using those materials for their enhanced properties or as emitters or sources of exciton, polariton, and/or BEC-forming light and/or electrical energy.

### BACKGROUND OF THE INVENTION

Bose-Einstein condensates (BECs) are formed using bosons or other atomic molecules e.g., other polyatomic molecules, quasi-particles, and photons. Bose-Einstein condensates (BECs) undergo a fusion reaction. When they are de-condensed, they release large amounts of energy. This energy can be used for various purposes.

An exciton is the bound state of an electron and electron hole which are attracted to each other by the electrostatic Coulomb force. The combination of an electron(s) and a positive hole(s) (an empty electron state in a valence band), may be free to move as a unit, or may be bound to a certain location. Because the electron(s) and the positive hole(s) have equal but opposite electrical charges, the exciton as a whole has no net electrical charge (though it transports energy). When an electron(s) in an exciton recombines with a positive hole(s), the original atom is restored, and the exciton vanishes. The energy of the exciton may be converted into light when this happens, or it may be transferred to an electron of a neighboring atom in the solid or fluid. If the energy is transferred to a neighboring electron, a new exciton is produced as this electron is forced away from its atom.

Long ago it was predicted that just like other bosons, excitons can form Bose-Einstein condensates (BECs), and also it has been suggested that quasi-particles, such as excitons can fulfill necessary conditions for a Bose-Einstein condensation (BEC). Therefore poly-electronic (whole number) exciton condensates and polaritons are formed under the correct conditions.

Devices/apparatuses relying on the manipulation of excitons, bound states of electrons and holes, hold great promise for the efficient interconnection between optical data transmission and electrical processing systems. While exciton-based transistor actions were successfully demonstrated in bulk semiconductor-based coupled quantum wells, the low temperature required for their operation limits their promise for practical applications.

Solid-state devices utilize particles and their quantum numbers for their operation, with electronics being the ubiquitous example. The development of such excitonic devices has so far been hindered by the absence of a suitable system enabling room-temperature manipulation of excitons and strongly limiting the expansion of the field.

Bose-Einstein condensates (BECs) are created in quantum optics and atomic physics for various purposes. They are not only used to reproduce complex situations in solids, but also to study some fundamental quantum properties. They may even be used to manipulate properties of certain materials.

To date various efforts are made to use Bose-Einstein condensates (BECs) and exciton techniques in electronic devices and fluid dynamics.

U.S. Patent application US20210217919A1 discloses an excitonic switch or transistor or coupling device including the excitonic device. The excitonic device includes at least one heterostructure being configured to generate interlayer excitons at high temperature or room temperature.

U.S. Patent application US20210405398A1 discloses an electro-optical converter that converts an electric signal to an optical signal. An optical signal is dragged from one optical channel to another optical channel using exciton polaritons that are generated in a layer that is adjacent to the optical channels.

U.S. Patent application US20120138115A1 discloses a thermoelectric device is produced by induction of opposing charges on the first surface and the second surface of the insulating layer spatially separated surface excitons are formed on the first and the second surfaces of the insulating layer, the spatially separated surface excitons generate a counterblow electrical current when a thermal gradient is provided across a longitudinal axis of the insulating layer. The surface excitons could potentially condense into a superfluid under appropriate conditions, giving rise to superfluidic thermoelectric current.

U.S. Patent application US20170115431A1 discloses optic and catalytic elements containing Bose Einstein condensates.

U.S. Patent U.S. Ser. No. 10/281,278B2 discloses superfluid quantum Interference Devices (SQUIDs) that measure phase differences existing in quasi-particles or matter-wave systems, and the related techniques for their use at room-temperatures. These quasi-particle circuits can be used to build analogs of electronic circuit elements, and offer an alternative to traditional electronics.

But the prior arts have miserably failed to overcome unwanted resistance and turbulence in fluid dynamics, boundary-layer resistance to flow, resistance in fluidity, optical, thermal, or electronic systems, inefficiency in acoustic systems, low percentage transmission and low refractive index in optics etc., nor have they provided a real-time means to manipulate these phenomenon.

Hence, there is a need for an improved technique/methods such as for enhancement/modification of fluid dynamics, reaction rates, combustion, acoustics, optics, electronics including bioelectronics, with passive and real-time modification of these properties

### SUMMARY OF THE INVENTION

In order to solve the above problems, the present invention is directed to Bose-Einstein condensates (BECs) and excitons formation at room temperature in certain materials, that enhances or modifies fluid dynamics, reactions/reaction rate, acoustics, optics and electronics, and generally allows for a reduction in resistive effects such as electrical resistance, drag, percent transmission and low refractive index in optics, along with allowing for real-time modification of these properties.

In one aspect of the present invention is a method of enhancing fluid dynamics, catalyzing reactions, enhancing acoustics, optics, electronics and real-time combustion modification/catalyzation, the method comprising: applying a first material, enhancing material properties by inducing the first material to enhance lattice vibrations/phonons for formation of Bose-Einstein condensates (BECs), where the precisely tuned lattice vibrations overcome coulomb forces to drive electrons together into further formation of the Bose-Einstein condensates (BECs), where the Bose-Einstein condensates (BECs) and excitons annihilate by emitting a photon of light, or transfer that energy to a neighboring electron, the emitted light having an energy necessary to drive the Bose-Einstein condensates (BECs) and excitons transition in another material, wherein maintaining and trapping the enhanced tuned lattice vibrations and collective excitations in a manner comparable to a novel polaritonic version of optical pumping, where the enhanced material properties of the first material is utilized directly, or the emitted light is being used to enhance properties of other materials, molecules, or fluids or is used as a power source.

In another aspect of the present invention is a method for enhancing BEC formation in materials, the method comprising: applying a first material, inducing the first material to enhance tuned lattice vibrations for formation of Bose-Einstein condensates (BECs) and excitons at room temperature, emitting a photon of light when the Bose-Einstein condensates (BECs) and excitons annihilate, where the emitted light having an energy necessary to drive the Bose-Einstein condensates (BECs) and excitons transition in another material, or where the energy is directly transferred to a neighboring electron, trapping the enhanced lattice vibrations of the first material, and utilizing the emitted light to enhance properties of the another materials, or by enhancing the properties of other materials through direct contact and/or electrovoltaic interactions.

In another aspect of the present invention is imparting a significant percentage of superconductivity and superfluidity to the materials or the fluids at room temperature. This being achieved through BEC systems formed using tuned collective lattice vibration systems.

In another aspect of the present invention is enhancing the lattice vibrations and BEC formation in the materials, the materials turn into emitters of light that is used to generate BECs in other materials (metal, insulator, semiconductor, biological molecules, etc.) and fluids, where many of such materials are insulators and metals not typically thought to be able to support exciton/Bose-Einstein condensates (BECs) formation within itself, especially at room temperature.

The summary of the invention is not intended to limit the key features and essential technical features of the claimed invention, and is not intended to limit the scope of protection of the claimed embodiments.

### BRIEF DESCRIPTION OF THE DRAWINGS

The following invention will be described with reference to the following drawings. The drawings and the associated descriptions are provided to illustrate embodiments of the invention and not to limit the scope of the invention. The accompanying drawings, which are incorporated in and form a part of this specification, illustrate embodiments of the invention and together with the description, serve to explain the principles of this invention.

FIG. 1 illustrates an exemplary method of enhancing tuned lattice vibrations (phonons and collective effects) and/or plasmons and achieving a greater rate of BEC formation, according to the embodiments of the present invention; and

FIG. 2 illustrates another exemplary method of enhancing tuned lattice vibrations (phonons and collective effects) and achieving a greater rate of BEC formation, according to the embodiments of the present invention.

### DETAILED DESCRIPTION OF THE INVENTION

The present invention will now be described more fully described hereinafter with reference to the accompanying drawings in which a preferred embodiment of the invention is shown. This invention may, however, be embodied in many different forms and should not be construed as being limited to the embodiment set forth herein. Rather, the embodiment is provided so that this disclosure will be thorough, and will fully convey the scope of the invention to those skilled in the art. Many aspects of the invention can be better understood with the references made to the drawings below. The components in the drawings are not necessarily drawn to scale. Instead, emphasis is placed upon clearly illustrating the components of the present invention. Moreover, like reference numerals designate corresponding parts through the several views in the drawings.

The foregoing description of embodiments of the invention has been presented for purposes of illustration and description. It is not intended to be exhaustive or to limit the invention to the precise form disclosed, and modifications and variations are possible in light of the above teachings or may be acquired from practice of the invention. The embodiments were chosen and described in order to explain the principles of the invention and its practical application to enable one skilled in the art to utilize the invention in various embodiments and with various modifications as are suited to the particular use contemplated.

As described herein with several embodiments, the present invention is methods for generating Bose-Einstein condensates (BECs) at room temperature in certain materials, through enhancing tuned lattice vibrations/collective effects, that enhances; fluid dynamics, reaction rate, acoustics, optics and electronics, along with providing a real-time method for modifying these properties.

As it is known that almost all solids with the exception of amorphous solids and glasses have periodic arrays of atoms which form a crystal lattice. The existence of the periodic crystal lattice in solid materials provides a medium for characteristic tuned vibrations. Between the lattice spacing, there are quantized vibrational modes called a phonon. Various studies suggested that the phonon is an important part of solid state physics, as they play an essential role in the physical properties of solids, the thermal and electrical conductivity of the materials. The long wavelength property of phonon also gives attributes to sounds in solids.

When the lattice is at equilibrium, each atom is positioned exactly at its lattice site. When an atom is displaced from its equilibrium site by a small amount, it will tend to return to its equilibrium position due to force acting on the atom, this results in lattice vibrations.

The lattice vibrations can be used to explain sound velocity, thermal properties, elastic properties and optical properties of materials. So herein with several embodiments in the present invention will be describing Bose-Einstein condensates (BECs) and excitons formation at room temperature in certain materials. Where in a small percentage of the time, due to lattice vibrations which overcome the Coulomb force to drive electrons together into condensates. Because these excitons and condensates exist at room temperature, they are unstable and eventually collapse, usually due to thermal-mechanical phonons. If lattice vibrations are enhanced, BEC/exciton formation and decay is also enhanced and thereby enhances various functions. For example, such as light productions are enhanced in the materials.

Further the present invention provides capitalizing or trapping the enhanced lattice vibrations in a manner that could be compared to a novel polaritonic version of optical pumping, when the BECs/exciton-polaritons collapse (decay or annihilate) they release a photon of light which has the specific energy necessary to drive the same excitonic/BEC electronic transition, either in another material, or in itself (as in the case of self-trapped excitons). Therefore, the enhanced material/fluid properties of the materials may be utilized directly, or the emitted light can be used to enhance the properties of another material, fluid, or molecule. When the emitted light lands on a receptive molecule it drives the formation of exciton/Bose-Einstein condensates (BECs). This newly-formed exciton/Bose-Einstein condensates (BECs) can accomplish significant work before annihilating. Thus, enhancing the lattice vibrations in the materials enhances exciton formation and exciton decay that enhances the light productions. It can be accomplished through exciton/Bose-Einstein condensates (BECs) formation in either the materials, fluids, or other mediums.

Due to the Lattice vibrations in the materials, these materials turn into emitters of light which can then be used to generate BECs/excitons in other materials, fluids, and molecules, or they can be used directly as power sources. In effect, it creates an BEC/exciton-beaming light-source, where one BEC/exciton disappears in one location and is formed in another through the quanta of light released in the first collapse. The host material does not need to be of the same material as the source to host BEC/excitonic activity in response to this light. Many host materials are insulators and metals not typically thought to be able to support exciton/Bose-Einstein condensates (BECs) formation within itself above quench temperature.

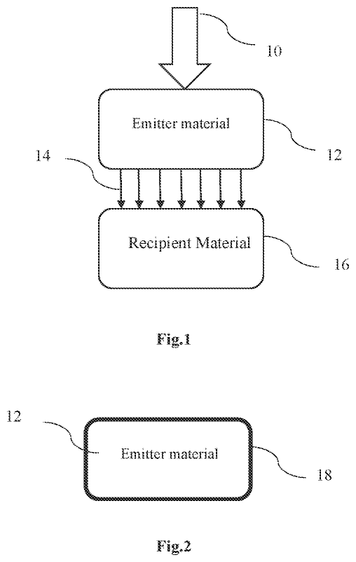

Now with specific reference to FIG. 1, FIG. 1 is an exemplary embodiment of the present invention at least an optical, a thermal, a thermal-electric, an electric, a capacitive, a magnetic, or any combination of these means used as stimulator 10 to enhance the lattice vibrations (phonons) and achieve a greater rate of exciton/BEC formation in the emitter material 12. The enhanced rate of exciton/BEC formation and collapse directly affects the rate of light productions 14. The light 14 can then be directed towards a Recipient material 16, either fluid or solid, or itself, to create BECs which enhance the material properties of the Recipient material 16.

FIG. 2 is another exemplary embodiment of the present invention, where the emitter material 12 is directly used to do work in the case of a coated wing 18. The coating 18 helps to mitigate/modify, or reduce skin-effects in aerodynamics, friction, and drag. These excitons/BECs are responsible for such work, such as, enhancing fluid dynamics, reducing friction, and enhancing energy transfer. Excitons and Bose-Einstein condensates (BECs) accomplish this by contributing a percentage of superfluidity (including optical superfluidity) and/or superconductivity (including thermal superconductivity) to the fluid or solid (Excitons/BEC passes superfluidity and superconductivity, further Excitons/BEC contributes these properties to the material/fluid properties based on their concentration within the material/fluid). In some embodiments without departing from the scope of the invention, the Excitons and Bose-Einstein condensates (BECs) can also be used to enhance acoustics, reduce noise, catalyze reactions, modify optics, increase energy transfer efficiency, and enhance conductors, fiber optics, and biological functions.

Embodiments of the present invention, various excitonic mesostructures are involved such as Fermi Spheres, polarons, and self-trapping excitons. This can be accomplished to produce desirable effects on acoustics, aerodynamics, fluid dynamics, energy transfer (light, electric, etc.) and electric motor efficiency.

The method of the present invention to achieve these effects as mentioned above is by selecting emitter materials (such as those used for superconductors and excitonic devices: strontium titanate, Perovskite's, etc.) that produce electronic condensates/excitons in small percentage at room temperature, and stimulate lattice vibrations and capacitative exciton formation which causes an increased rate of exciton formation and annihilation emission through enhanced lattice vibrations. While the vibrations are not synchronized, there are sufficient lattice vibrations of the correct type to cause the formation of the Excitons and Bose-Einstein condensates (BECs) and excitons. However, because thermal energy phonons are present in abundance, the exciton may almost immediately decay, while others remain longer, giving off a quanta of light. That quanta is directly related to the energy necessary to drive an excitonic/BEC transition. As the light from the decaying exciton radiates away from the device or coating (Coatings may be stimulated sufficiently with thermal energy of materials, electronics, machines, etc.), it then tends to be absorbed by structures in the vicinity which can resonate at that frequency. Again, a case of silicone dioxide is a prime example, where the lone silicon and its neighboring oxygen resonate to form an exciton/condensate at 2.8 ev. Again, by inducing thermal mechanical phonons, and polarons, the materials are converted into emitters for the specific electromagnetic wavelength and frequency of light necessary to produce the same transition/condensation in surrounding materials and fluids (some are at optical frequencies such as 2.8 ev, while most are not).

Thus, according to one or more examples of the present disclosure as BECs and excitons are formed in the material, and then annihilate, releasing a photon of light, the photon given off has the same potential energy which was involved in generating the electronic condensation/transition. Because BECs and excitons can be formed in fluids, fluid-flow can be improved or modified; as BECs and excitons transmit energy with orders of magnitude less resistance than single electrons do, they are able to achieve significant work before decaying. What is also significant is that the exciton creates a quantum electronic substrate, which is lower than the energy of the excited state for the same system, allowing for catalyzation, in real time, which is related to light intensity. This is particularly useful for modifying rates of combustion in real time, both for work and for entertainment purposes, by modifying the concentration of exciton formation through light intensity. For entertainment flames or other reactions, could be modulated to the sound of music, light, etc, while afterburners could be computer modulated to optimize efficiency. As this light radiates away from the emitter 12, and lands on surrounding fluids, and materials, it is absorbed differently, and can sometimes generate an electronic condensate, yet within a material which is not traditionally thought of as being able to support BEC/excitonic behavior.

As mentioned before, one such example is the case of typical glass (Silicon Dioxide), where a lone silicon and a neighboring oxygen interact to form an exciton (APPROX 2.8 EV), modifying or enhancing the optical properties of the glass (refractive index modification or enhancement, % transmission enhancement). This occurs due to a type of resonance, which may occur at the atomic, subatomic, molecular, inter or intramolecular level. Their formation can be stimulated, especially through electromagnetic, capacitive, thermal mechanical phonon, or any combination of these means. Once these Bose-Einstein condensates are formed in a material, they are able to perform work far more efficiently than individual electrons could. This is primarily due to spin alignment, charge cancellation (Excitons are electrically neutral species), and excitonic chains and systems. Eventually the exciton collapses and releases a photon of the exact wavelength and frequency necessary to cause the same transition which is formed. In this manner a surface, material, or area can become saturated with excitons/Bose-Einstein condensates (BECs), once an equilibrium is reached between BEC/exciton formation and collapse. In this way a non-conducting, resistive material can host BEC/excitons for a considerable amount of time, until lattice vibrations, or sufficient energy has entered the system to decouple the electrons. An area may “glow” at these BEC/excitonic frequencies after being exposed to light-source/emitter 12 for moments, or some days, until the excitonic activity has completely ceased.

Hence, the technology and method of the present invention is particularly useful in the world of optical, acoustic, electrical and fluid-dynamic, and biotech engineering. For example, an internal combustion engine could have this technology applied on all fluid-bearing surfaces such as intakes, exhausts, cylinder heads, pistons, and all ignition and electronic components, through the use of this thermal and electromagnetic method of stimulated emission.

Advantageously, the method of the present embodiment can define or be used as imparting a significant percentage of superconductivity and superfluidity to materials and fluids at room temperature.

One more advantage of the present invention is providing a radiant source to materials and fluids to enhance their properties. Radiant emitters can be used to broadcast, for example, at the nosecone of a rocket, or in a professional astronomy installation.

One more advantage of the present invention is that the materials and fluids can be modulated in real time at high frequency (may be used to transmit data).

One more advantage is the invention may be used without electrification at room temperature as this is sufficient energy to induce some mechanical phonons which then induce the Bose-Einstein condensates (BECs) formation.

The invention will be used as an inclusion in a material where wavelengths involved travel through many everyday mediums such as plastic and paint, broadening its application. They may even be used as an inclusion or coating within ballistics materials and ammunition to enhance ballistics and kinetics.

One more advantage of the present invention is that it is effective on gasses, fluids, and light, not simply solid materials.

There has thus been outlined, rather broadly, the more important features of the invention in order that the detailed description thereof may be better understood, and in order that the present contribution to the art may be better appreciated. There are additional features of the invention that will be described hereinafter, and which will form the subject matter of the claims appended hereto. The features listed herein, and other features, aspects and advantages of the present invention will become better understood with reference to the following description and appended claims.

Further advantages and improvements may very well be made to the present invention without deviating from its scope. Although the invention has been shown and described in what is conceived to be the most practical and preferred embodiment, it is recognized that departures may be made therefrom within the scope and spirit of the invention, which is not to be limited to the details disclosed herein but is to be accorded the full scope of the claims so as to embrace any and all equivalent devices and apparatus.

The foregoing description of embodiments of the disclosure has been presented for purposes of illustration and description. It is not intended to be exhaustive or to limit the disclosure to the precise form disclosed, and modifications and variations are possible in light of the above teachings or may be acquired from practice of the disclosure. The embodiments were chosen and described in order to explain the principals of the disclosure and its practical application to enable one skilled in the art to utilize the disclosure in various embodiments and with various modifications as are suited to the particular use contemplated.

It should be understood that while the preferred embodiments of the invention are described in some detail herein, the present disclosure is made by way of example only and that variations and changes thereto are possible without departing from the subject matter coming within the scope of the following claims, and a reasonable equivalency thereof, which claims I regard as my invention.

All of the material in this patent document is subject to copyright protection under the copyright laws of the United States and other countries. The copyright owner has no objection to the facsimile reproduction by anyone of the patent document or the patent disclosure, as it appears in official governmental records but, otherwise, all other copyright rights whatsoever are reserved.

What is claimed is:

1. A method of enhancing material properties including at least one selected in fluid dynamics, catalyzing reactions, acoustics, optics, electronics and real-time combustions, the method comprising:
applying a first material, or mixture of materials, enhancing material properties by inducing the first material/mixture to enhance lattice vibrations and capacitative formation of Bose-Einstein condensates (BECs) and excitons at room temperature, where the lattice vibrations overcome coulomb forces to drive electrons together into further formation of the Bose-Einstein condensates (BECs) and excitons,
where the Bose-Einstein condensates (BECs) and excitons annihilate by emitting a photon of light, the emitted light having an energy necessary to drive the Bose-Einstein condensates (BECs) and excitons transition in another material,
wherein trapping the enhanced lattice vibrations in a manner to a novel polaritronic version of optical pumping, where the enhanced material properties of the first material is utilized directly, or the emitted light is being used to enhance properties of the another materials.

2. The method of claim 1, wherein the lattice vibrations of the first material are enhanced together with enhancement of the exciton formation and annihilation, thus enhances light productions.

3. The method of claim 1, wherein inducing the first material to enhance the lattice vibrations by using at least one selected from an optical, a thermal, a thermal-electric, an electric, a capacitive, a magnetic, or any combination.

4. The method of claim 1, wherein an enhanced rate of exciton formation and annihilation is directly proportional to a rate of a light emission.

5. The method of claim 1, wherein the emitted light be directed towards the materials, either fluids or solids, or itself as in the case of self-trapped excitons, to create excitons that enhances material properties of another material.

6. The method of claim 1, wherein the first material is emitter material such as at least one selected from strontium titanate, Perovskite's, etc.

7. The method of claim 1, wherein the Lattice vibrations in the materials, the materials turn into emitters of light that is used to generate excitons in other materials and fluids, where many of such materials are insulators and are not typically thought to be able to support exciton/Bose-Einstein condensates (BECs) formation within itself.

8. The method of claim 6, wherein the emitter material can be used directly in coating of the another material to mitigate or reduce skin-effects in aerodynamics, friction, and drag, where the excitons are responsible for enhancing such as fluid dynamics, reducing friction, and/or enhancing energy transfer.

9. The method of claim 1, further used in imparting a significant percentage of superconductivity and superfluidity to the materials or the fluids at room temperature.

10. A method for enhancing lattice vibrations in materials, the method comprising:
applying a first material, inducing the first material to enhance lattice vibrations and/or electrostatic/capacitative for formation of Bose-Einstein condensates (BECs) and excitons at room temperature,
emitting a photon of light when the Bose-Einstein condensates (BECs) and excitons annihilate, where the emitted light having an energy necessary to drive the Bose-Einstein condensates (BECs) and excitons transition in another material, or itself,
trapping the enhanced lattice vibrations of the first material, and
utilizing the emitted light to enhance properties of another materials.

11. The method of claim 10, wherein the lattice vibrations of the first material is used in enhancement of the material properties of another material.

12. The method of claim 10, wherein inducing the first material to enhance the lattice vibrations by using at least one selected from an optical, a thermal, a thermal-electric, an electric, a capacitive, a magnetic, or any combination.

13. The method of claim 10, wherein an enhanced rate of exciton formation and annihilation is directly proportional to a rate of a light emission.

14. The method of claim 10, wherein the emitted light be directed towards the materials, either fluids or solids, or itself as in the case of self-trapped excitons, to create excitons that enhance material properties of another material.

15. The method of claim 1, wherein the first material is emitter material such as at least one selected from strontium titanate, Perovskite's, etc.

16. The method of claim 10, wherein the Lattice vibrations in the materials, the materials turn into emitters of light that is used to generate excitons in other materials and fluids, where many of such materials are insulators and are not typically thought to be able to support exciton/Bose-Einstein condensates (BECs) formation within itself.

17. The method of claim 15, wherein the emitter material can be used directly in coating of the another material to mitigate or reduce skin-effects in aerodynamics, friction, and drag, where the excitons are responsible for enhancing such as fluid dynamics, reducing friction, and enhancing energy transfer.

18. The method of claim 10, wherein enhancing the Lattice vibrations enhances material properties including at least one selected in fluid dynamics, catalyzing reactions, acoustics, optics, electronics and real-time combustions.

19. The method of claim 10, further used in imparting a significant percentage of superconductivity and superfluidity to itself or other materials or fluids at room temperature.

20. A method of enhancing material properties including at least one selected in fluid dynamics, catalyzing reactions, acoustics, optics, electronics and real-time combustions, the method comprising:
applying a first material, or mixture of materials, enhancing material properties by inducing the first material/mixture to enhance lattice vibrations and capacitative formation of Bose-Einstein condensates (BECs) and excitons at room temperature, where the lattice vibrations overcome coulomb forces to drive electrons together into further formation of the Bose-Einstein condensates (BECs) and excitons,
where the Bose-Einstein condensates (BECs) and excitons annihilate by emitting a photon of light, the emitted light having an energy necessary to drive the Bose-Einstein condensates (BECs) and excitons transition in another material,
wherein trapping the enhanced lattice vibrations in a manner to a novel polaritronic version of optical pumping, where the enhanced material properties of the first material is utilized directly, or the emitted light is being used to enhance properties of the another materials, wherein the lattice vibrations of the first material are enhanced together with enhancement of the exciton formation and annihilation, thus enhances light productions, wherein inducing the first material to enhance the lattice vibrations by using at least one selected from an optical, a thermal, a thermal-electric, an electric, a capacitive, a magnetic, or any combination, wherein an enhanced rate of exciton formation and annihilation is directly proportional to a rate of a light emission, wherein the emitted light be directed towards the materials, either fluids or solids, or itself as in the case of self-trapped excitons, to create excitons that enhances material properties of another material, wherein the first material is emitter material such as at least one selected from strontium titanate, Perovskite's, etc, wherein the Lattice vibrations in the materials, the materials turn into emitters of light that is used to generate excitons in other materials and fluids, where many of such materials are insulators and are not typically thought to be able to support exciton/Bose-Einstein condensates (BECs) formation within itself, wherein the emitter material can be used directly in coating of the another material to mitigate or reduce skin-effects in aerodynamics, friction, and drag, where the excitons are responsible for enhancing such as fluid dynamics, reducing friction, and/or enhancing energy transfer, further used in imparting a significant percentage of superconductivity and superfluidity to the materials or the fluids at room temperature.
